(19) United States
(12) Patent Application Publication
(10) Pub. No.: US 2026/0004837 A1
(43) Pub. Date: Jan. 1, 2026

(54) HIGH SPEED UNLIMITED ENDURANCE NON-VOLATILE RAM INCLUDING SPIN-TRANSFER TORQUE MAGNETIC TUNNEL JUNCTION (STT-MTJ) STRUCTURES

(71) Applicant: IM2 Solutions, Inc., Pleasanton, CA (US)

(72) Inventors: Adrian ONG, Pleasanton, CA (US); Tim LAO, Sacramento, CA (US)

(73) Assignee: IM2 Solutions, Inc., Pleasanton, CA (US)

(21) Appl. No.: 19/253,872

(22) Filed: Jun. 29, 2025

Related U.S. Application Data
(60) Provisional application No. 63/666,166, filed on Jun. 29, 2024.

(51) Int. Cl. G11C 11/16; G11C 11/417

(52) U.S. Cl. CPC G11C 11/1697; G11C 11/417

(57) ABSTRACT

A non-volatile static random-access memory (NVSRAM) device includes at least one array of NVSRAM cells. Each NVSRAM cell includes an SRAM unit and an MRAM unit. The SRAM unit includes at least six transistors, and the MRAM unit includes at least two-transistors and two magnetic tunnel junction (MTJ) structures. The SRAM units are accessed during normal read/write operations to allows for fast access to the NVSRAM cells with unlimited endurance and without read/write error rate issues. Hidden MRAM write operations in NVSRAM cells that are not accessed for normal read/write operations may be activated manually or automatically to back up the data stored in the corresponding SRAM units. When the NVSRAM device loses power, data stored in the SRAM units are lost, while the data backed-up in corresponding MRAM units are retained. When power is restored, an automatic data restore write cycle is started, during which the SRAM units recover their data from their corresponding MRAM units.

### CROSS-REFERENCE TO RELATED APPLICATIONS

The present application claims the benefit of priority from U.S. Provisional Application No. 63/666,166, filed Jun. 29, 2024, which is incorporated in its entirety by reference herein.

### FIELD OF THE DISCLOSURE

The present disclosure relates to computer memory technology, and more specifically to a high speed unlimited endurance non-volatile random access memory (RAM) including spin-transfer torque magnetic tunnel junction (STT-MTJ) structures.

### BACKGROUND OF THE DISCLOSURE

Static random access memory (SRAM) loses its content when powered down, and is thus volatile memory. Memory that retains its data without power is classified as nonvolatile memory. Examples of nonvolatile memory are nonvolatile SRAM (NVSRAM), ferroelectric RAM (F-RAM™), electrically erasable programmable ROM (EEPROM), flash memory, and magnetoresistive random-access memory (or MRAM). Nonvolatile memory is used in applications in which critical data must be kept after power is removed or when power is interrupted during operation.

NVSRAM is a type of nonvolatile memory that combines SRAM features with features of non-volatile memory to attain nonvolatility. It has the advantages of high speed and nonvolatile storage at relatively low cost compared to alternative solutions to retain data on devices when power is interrupted.

### SUMMARY

A non-volatile static random-access memory (NVSRAM) device includes an array of NVSRAM cells. Each NVSRAM cell includes a static random access memory (SRAM) unit and a spin-transfer torque magneto-resistive random-access memory (STT-MRAM or MRAM) unit. The SRAM unit includes at least six transistors (6-T SRAM), while the STT-MRAM unit includes at least two-transistors and two magnetic tunnel junction (MTJ) structures (2T2M STT-MRAM). Thus, the NVSRAM cell is sometimes referred to as an 8T2M-NVSRAM. The NVSRAM device can be accessed for read/write operations. During normal read/write operations, read and write to the 8T2M-NVSRAM cells in the NVSRAM device is done in the 6-T SRAM units. This allows for fast access to the NVSRAM cells with unlimited endurance and without read/write error rate issues. During stand-by or while other portions of NVSRAM device is active, a hidden MRAM write operations in NVSRAM cells that are not accessed for normal read/write operations may be activated manually or automatically. In this operation, differential bits from corresponding SRAM units are written into the MRAM units using internally generated signals (i.e., signals generated on the device). When power to the device is off, the SRAM units lose their data, while the data in the corresponding STT-MRAM units are retained. When power is restored, an automatic restore write cycle is started, during which the SRAM units recover their data from their corresponding MRAM units.

According to some embodiments, a memory device comprises one or more memory arrays, each memory array including memory cells arranged in n rows and m columns. The memory array further includes n variable supply voltage lines, each of the n variable supply voltage lines being coupled to memory cells in a respective row of the n rows. The memory array further includes n SRAM word lines, each of the n SRAM word lines being coupled to memory cells in a respective row of the n rows. The memory array further includes n MRAM word lines, each of the n MRAM word lines being coupled to memory cells in a respective row of the n rows. The memory array further includes m bit line pairs, each bit line pair of the m bit line pairs being coupled to memory cells in a respective column of the m columns.

In some embodiments, each memory cell includes an SRAM unit and an MRAM unit. The SRAM unit includes first and second memory nodes programmable via the corresponding SRAM word line and the corresponding bit line pair to be at two complementary voltage levels, respectively. The MRAM unit includes a first magnetic tunnel junction (MTJ) circuit, and a second MTJ circuit. The first MTJ circuit includes a first transistor and a first MTJ structure. The first MTJ structure has a first pin layer and a first free layer on opposite sides of a first tunnel barrier layer. The second MTJ circuit includes a second transistor and a second MTJ structure. The second MTJ structure has a second pin layer and a second free layer on opposite sides of a second tunnel barrier layer.

In some embodiments, the first transistor has a first gate coupled to a corresponding MRAM word line and is configured to connect the first free layer to a first bit line of the corresponding bit line pair, or to connect the first pin layer to the first memory node, in response to a voltage on the corresponding MRAM word line exceeding a MTJ programming threshold. The second transistor has a second gate coupled to the corresponding MRAM word line and is configured to connect the second free layer to a second bit line of the corresponding bit line pair, or to connect the second pin layer to the second memory node, in response to the voltage on the corresponding MRAM word line exceeding the MTJ programming threshold.

In some embodiments, the first MTJ structure is configured to flip from an antiparallel (AP) state to a parallel (P) state in response to a first electric current from the first bit line to the first memory node exceeding a first threshold. The second MTJ structure is configured to flip from an parallel (P) state to an antiparallel (AP) state in response to a second electric current from the second memory node to the second bit line exceeding a second threshold.

In some embodiments, the first MTJ structure is configured to flip from an parallel (P) state to an antiparallel (AP) state in response to a third electric current from the first memory node to the first bit line exceeding the second threshold, and the second MTJ structure is configured to flip from an antiparallel (AP) state to a parallel (P) state in response to a fourth electric current from the second bit line to the second memory node exceeding the first threshold. In some embodiments, the first threshold is different from the second threshold.

In some embodiments, the memory device further comprises a variable supply voltage control circuit configured to control the variable supply voltage lines. The variable supply voltage control circuit is configured to output a first voltage to the corresponding variable supply voltage line when the first and second memory nodes are being programmed via the corresponding word line and the corresponding bit line pair to be at two complementary voltage levels, respectively. In some embodiments, the variable supply voltage control circuit is configured to output a second voltage to the corresponding variable supply voltage line to enable the first electric current to exceed the first threshold and the second electric current to exceed the second threshold, the second voltage being higher than the first voltage.

In some embodiments, the first transistor has a first source terminal and a first drain terminal, one of the first source terminal and the first drain terminal is coupled to the first free layer, and the other one of the first source terminal and the first drain terminal is coupled to the first bit line. In some embodiments, the second transistor has a second source terminal and a second drain terminal, one of the second source terminal and the second drain terminal is coupled to the second free layer, and the other one of the second source terminal and the second drain terminal is coupled to the second bit line.

In some embodiments, the first transistor has a first source terminal and a first drain terminal, one of the first source terminal and the first drain terminal is coupled to the first pin layer, and the other one of the first source terminal and the first drain terminal is coupled to the first memory node.

In some embodiments, the second transistor has a second source terminal and a second drain terminal, one of the second source terminal and the second drain terminal is coupled to the second pin layer, and the other one of the second source terminal and the second drain terminal is coupled to the second memory node.

In some embodiments, the memory device further comprises a data recovery control logic configurable to, after the memory device experiences power loss and in response to power to the memory device having been restored, cause the memory device to perform data recovery operations to recover data values stored in the memory cells immediately before the power loss, the data recovery operations including a first data recovery operation to recover data in an i^{th} row of the rows, and a second data recovery operation to recover data in an j^{th} row of the rows.

In some embodiments, the first data recover operation includes: applying the second voltage to an i^{th} MRAM word line of the n MRAM word lines during an i^{th} data recovery period, the i^{th} MRAM word line corresponding to the i^{th} row; and increasing a voltage on an i^{th} variable supply voltage line of the n variable supply voltage lines to the first voltage during the i^{th} data recovery period, the i^{th} variable supply voltage line corresponding to the i^{th} row.

In some embodiments, the first data recover operation includes: applying the second voltage to an j^{th} MRAM word line of the n MRAM word lines during an j^{th} data recovery period subsequent to the i^{th} data recovery period, the j^{th} MRAM word line corresponding to the j^{th} row; and increasing a voltage on an j^{th} variable supply voltage line of the n variable supply voltage lines to the first voltage during the j^{th} data recovery period, the j^{th} variable supply voltage line corresponding to the j^{th} row.

In some embodiments, the m bit line pairs are kept grounded during the data recovery operations.

According to some embodiments, a method of operating a memory device comprises: applying a first voltage to the corresponding variable supply voltage line during a first time period; applying a second voltage to the corresponding MRAM word line during a second time period, the second time period overlapping with at least part of the first time period; connecting a first bit line of the corresponding bit line pair to a third voltage during a third time period, the third time period overlapping at least partially with the first timer period; and connecting a second bit line of the corresponding bit line pair to a fourth voltage during a fourth timer period, the fourth time period overlapping at least partially with the third timer period, one of the third voltage and the fourth voltage is a supply voltage, and the other one of the third voltage and the fourth voltage is a reference voltage.

In some embodiments, the method further comprises applying a fifth voltage to the corresponding variable supply voltage line when the first and second memory nodes are being programmed via the corresponding word line and the corresponding bit line pair to be at two complementary voltage levels, respectively.

In some embodiments, the method further comprises, after the memory device experiencing power loss and in response to power to the memory device having been restored, performing data recovery operations to recover data values stored in the memory cells immediately before the power loss, the data recovery operations including a first data recovery operation to recover data in an i^{th} row of the rows, and a second data recovery operation to recover data in an j^{th} row of the rows.

In some embodiments, the first data recover operation includes: applying the second voltage to an i^{th} MRAM word line of the n MRAM word lines during an i^{th} data recovery period, the i^{th} MRAM word line corresponding to the i^{th} row; and increasing a voltage on an i^{th} variable supply voltage line of the n variable supply voltage lines to the first voltage during the i^{th} data recovery period, the i^{th} variable supply voltage line corresponding to the i^{th} row.

In some embodiments, the second data recover operation includes: applying the second voltage to a j^{th} MRAM word line of the n MRAM word lines during a j^{th} data recovery period subsequent to the i^{th} data recovery period, the j^{th} MRAM word line corresponding to the j^{th} row; and increasing a voltage on a j^{th} variable supply voltage line of the n variable supply voltage lines to the first voltage during the j^{th} data recovery period, the jthh variable supply voltage line corresponding to the j^{th} row;

In some embodiments, the m bit line pairs are kept grounded during the data recovery operations.

According to some embodiments, a method of operating a NVSRAM memory device comprises: writing into a plurality of memory cells during one or more write operations, the plurality of memory cells including first memory cells and second memory cells, wherein the one or more write operations cause the SRAM unit in each of the first memory cells to store a first data value and the SRAM unit in each of the second memory cells to store a second data value.

In some embodiments, the method of operating a NVSRAM memory device further comprises backing-up the first memory cells concurrently during a first time period, including, for each respective memory cell of the plurality of memory cells, applying a first voltage to a variable supply voltage line coupled to the each respective memory cell, applying a second voltage to a MRAM word line coupled to the each respective memory cell, connecting a first bit line of a bit line pair coupled to the each respective memory cell to a third voltage, and connecting a second bit line of the bit line pair coupled to the each respective memory cell to a fourth voltage.

In some embodiments, the method of operating a NVSRAM memory device further comprises backing-up the second memory cells concurrently during a second time period subsequent to the first time period, including, for each particular memory cell of the particular of memory cells, applying the first voltage to a variable supply voltage line coupled to the each particular memory cell, applying the second voltage to a MRAM word line coupled to the each particular memory cell, connecting a first bit line of a bit line pair coupled to the each particular memory cell to the fourth voltage, and connecting a second bit line of the bit line pair coupled to the each particular memory cell to the third voltage.

In some embodiments, backing up the first memory cells causes a first current to flow from the SRAM unit of each respective memory cell to flow through a first MTJ structure in the MRAM unit of the each respective memory cell to the first bit line and a second current to flow from the second bit line through a second MTJ structure in the MRAM unit of the each respective memory cell to the SRAM unit of the each respective memory cell, the first current setting the first MTJ structure to a high resistance (antiparallel or AP) state, the second current setting the second MTJ structure to a low resistance (parallel or P) state, resulting in the first data value stored in the SRAM unit in each respective first memory cell of the first memory cells to be written into the MRAM unit in the each respective first memory cell.

In some embodiments, backing up the second memory cells causes a third current to flow from the first bit line through a first MTJ structure in the MRAM unit of the each particular second memory cell to the SRAM unit of the each particular memory cell and a fourth current to flow from the SRAM unit of the each particular memory cell to flow through a second MTJ structure in the MRAM unit of the each particular memory cell to the second bit line, the third current setting the first MTJ structure to low resistance (parallel or P) state, the second current setting the second MTJ structure to a high resistance (antiparallel or AP) state, resulting in the second data value stored in the SRAM unit in each particular second memory cell of the second memory cells to be written into the MRAM unit in the each particular second memory cell.

In some embodiments, after the NVSRAM memory device experiences power loss and in response to power to the memory device having been restored, the method of operating the NVSRAM device further comprises performing data recovery operations to recover data values stored in the memory cells immediately before the power loss, the data recovery operations including a first data recovery operation to recover data in a first row and a second data recovery operation to recover data in a second row. The plurality of memory cells are in the first row, and one or more memory cells in a second row are accessed for read/write operation during the first time period and/or the second time period.

In some embodiments, the first data recover operation includes: applying the second voltage to a first MRAM word line of the n MRAM word lines during a first data recovery period, the first MRAM word line corresponding to the first row; and increasing a voltage on an first variable supply voltage line of the n variable supply voltage lines to the first voltage during the first data recovery period, the first variable supply voltage line corresponding to the first row.

In some embodiments, the second data recover operation includes: applying the second voltage to a second MRAM word line of the n MRAM word lines during a second data recovery period subsequent to the first data recovery period, the second MRAM word line corresponding to the second row; and increasing a voltage on a second variable supply voltage line of the n variable supply voltage lines to the first voltage during the second data recovery period, the second variable supply voltage line corresponding to the second row.

In some embodiments, the m bit line pairs are kept grounded during the data recovery operations.

### BRIEF DESCRIPTION OF THE DRAWINGS

FIG. 1A is a block diagram of a NVSRAM device according to certain embodiments.

FIG. 1B is a block diagram of the NVSRAM core circuitry according to certain embodiments.

FIG. 1C is a block diagram illustrating a read/write circuit in the read/write circuitry according to certain embodiments.

FIGS. 3A and 3B are circuit diagrams illustrating an NVSRAM cell in the NVSRAM core circuitry according to certain embodiments.

FIGS. 3C and 3D are circuit diagrams of an MTJ circuit that can be programmed to switch between a low-resistance state (parallel or P-state) and a high-resistance state (anti-parallel or AP-state), according to certain embodiments.

FIG. 4 is a waveform diagram showing simulated waveforms of various signals associated with a series of operations involving two NVSRAM cells according to certain embodiments.

FIG. 5A is a diagram illustrating currents, voltages, and transistor states in an NVSRAM cell during an operation to write “1” into an SRAM unit of an NVSRAM cell according to certain embodiments.

FIG. 5B is a diagram illustrating currents, voltages, and transistor states in an NVSRAM cell during an operation to write “0” into an SRAM unit of an NVSRAM cell according to certain embodiments.

FIG. 6A is a diagram illustrating currents, voltages, and transistor states in an NVSRAM cell during an operation in which “0” is written into an MRAM unit of an NVSRAM cell according to certain embodiments.

FIG. 6B is a diagram illustrating currents, voltages, and transistor states in an NVSRAM cell during an operation in which “1” is written into an MRAM unit of an NVSRAM cell according to certain embodiments.

FIG. 7 is a diagram illustrating an operation to recover data from the MRAM unit to the SRAM unit of an NVSRAM cell according to certain embodiments.

### DESCRIPTION OF THE EMBODIMENTS

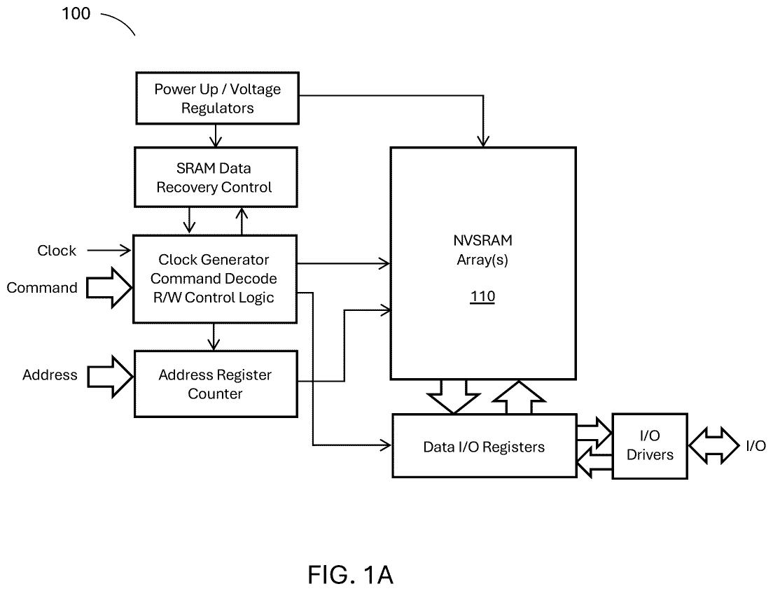

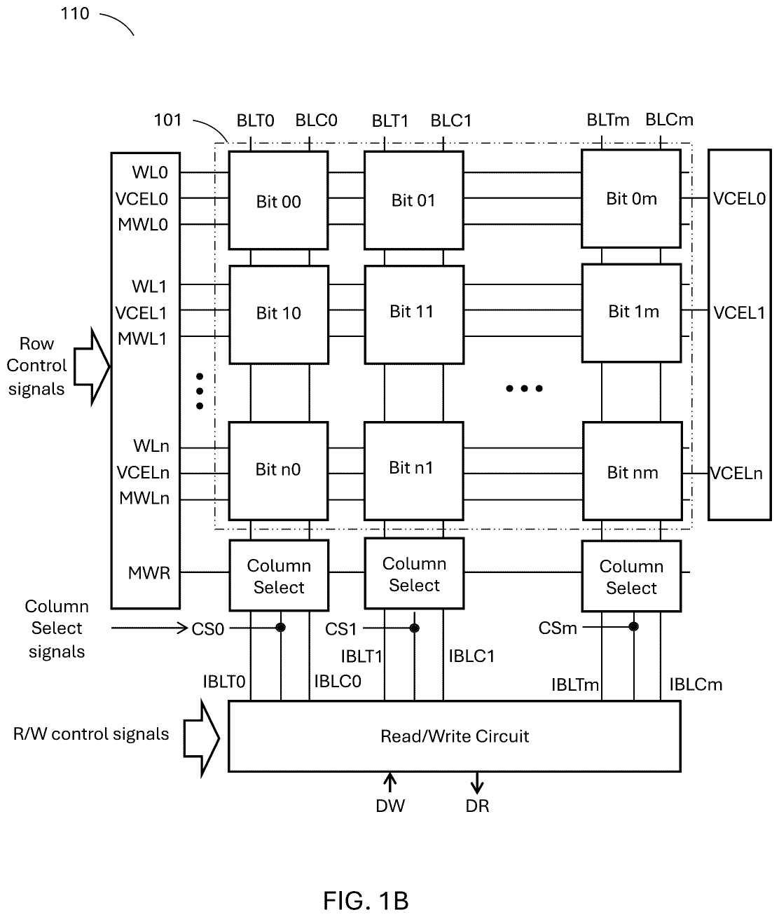

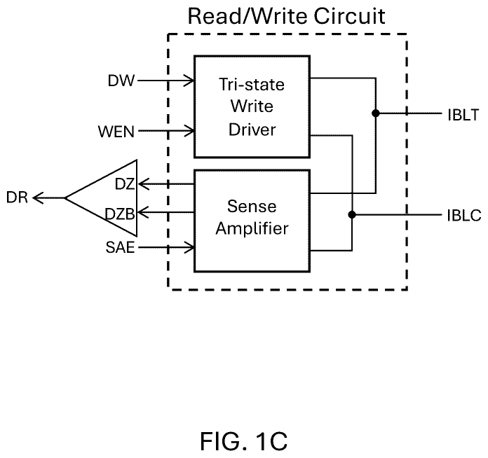

FIG. 1A is a block diagram of a NVSRAM device 100 according to certain embodiments. As shown, the NVSRAM device 100 includes NVSRAM core circuitry 110, which includes one or more NVSRAM arrays, and peripheral circuitry, which includes power up/voltage regulators, a SRAM data recovery control device, clock generator, command decode read/write (R/W) control logic, an address register counter, data I/O registers, and I/O drivers.

FIG. 1B is a block diagram of an n×m MRAM array 101 and associated control circuitry in the NVSRAM core circuitry 110 according to certain embodiments. As shown, the control circuitry includes variable supply voltage (VCEL) control circuitry, row control circuitry, column select circuitry, and a read/write control circuit. The NVSRAM array 101 includes n rows and m columns of NVSRAM cells (Bit 00, . . . , Bit nm). Each row of the NVSRAM cells (e.g., row 0 including Bit 00, B 01, . . . , Bit 0m) is coupled to the VCEL control circuitry via a corresponding voltage cell (VCEL) line (e.g., VCEL0), and to the row control circuitry via a corresponding set of word lines (e.g., WL0 and WLM0). Each column of the NVSRAM cells (e.g., column 0 including Bit 00, Bit 10, . . . , Bit n0) is coupled to a corresponding bit line pair (e.g., BLT0 and BLC0), which is coupled to a corresponding column select driver in the column select circuitry, which in turn is coupled to the read/write circuit. Each word line (e.g., WL0) is used to select a corresponding row of memory cells (e.g., row 0), each bit line pair (e.g., BLT0 and BLC0) is used to control a data read or write operation on a memory cell in a corresponding column (e.g., column 0) in a selected row, and each column select circuit is configured to control a corresponding pair of bit lines. The read/write circuit is configured to receive read/write (R/W) control signals and control the column select circuitry in response to the R/W control signals.

FIG. 1C is a block diagram illustrating a read/write circuit in the read/write circuitry according to certain embodiments. As shown, the read/write circuit includes a tri-state write driver and a sense amplifier similar to those in conventional SRAM circuits. In some embodiments, BLT<0:m> and BLC<0:m> can be multiplexed to IBLT<0:j> and IBTC<0:j>, where j may be a fraction of m. Also, each CS may select multiple BLT/BLC pairs. For example, one CS may select 4 BLT/BLC-pairs. Each BLT/BLC pair can be connected to IBLT/IBLC corresponding to each Read/Write circuit. The read/write circuit also receives data write (DW) and write enable (WEN) signals and output data read (DR) signal(s) (which are driven by the DZ/DZB signals) . . .

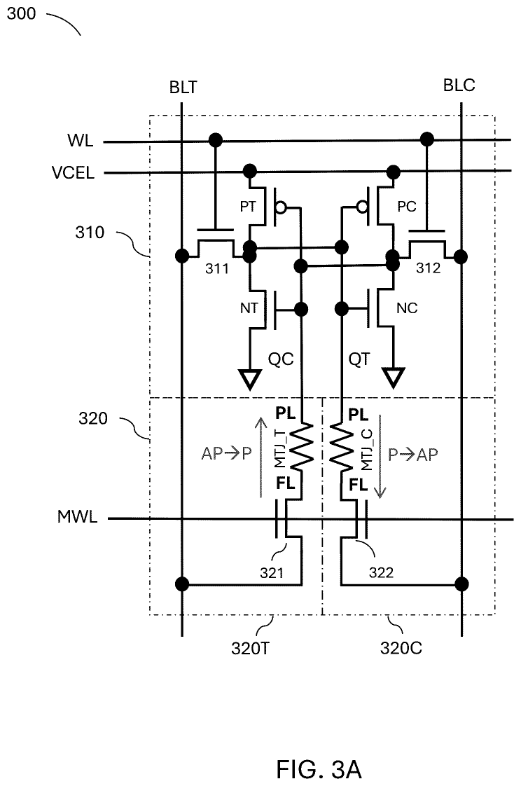

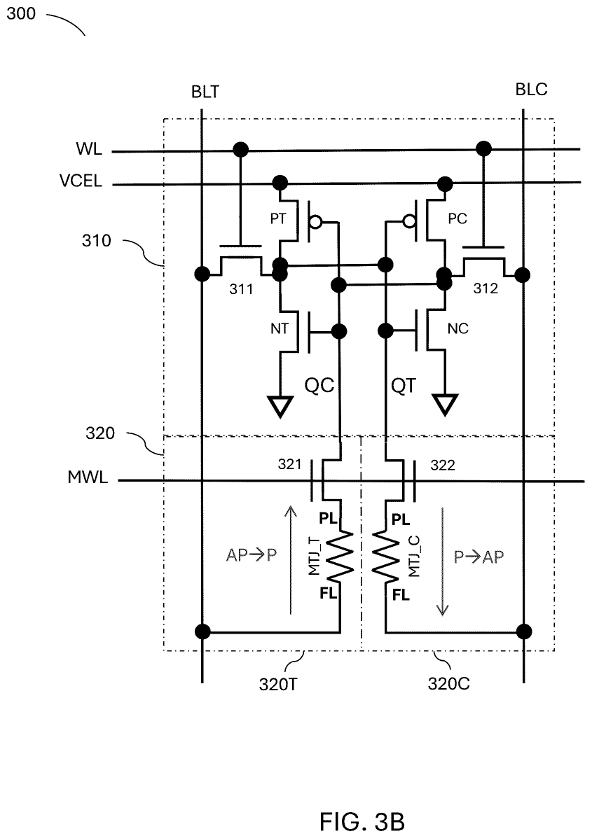

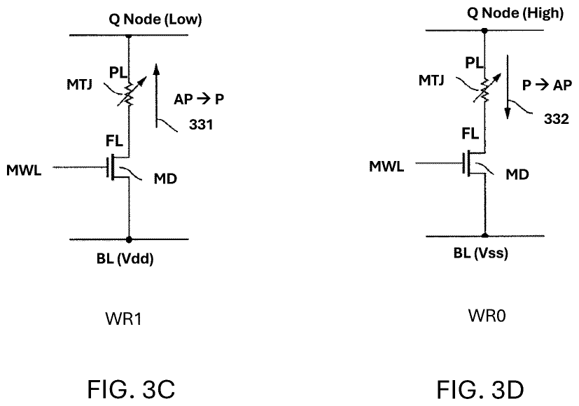

FIGS. 3A and 3B illustrate an NVSRAM cell 300, which can be a bit cell, Bit (i, j) in the NVSRAM array 101 according to certain embodiments, where i=0, 1, . . . , n, and j=0, 1, . . . , m. As shown, the NVSRAM cell 300 is coupled to a voltage cell line VCEL, two complementary bit lines BLT and BLC, an SRAM word line WL, and a MRAM word line MWL, according to certain embodiments. As shown, the NVSRAM cell 300 includes an SRAM unit 310 and a MRAM unit 320. In certain embodiments, the SRAM unit 310 is a six-transistor SRAM unit (6-T SRAM), although an SRAM unit with additional transistors can also be used. As shown, four of the six transistors in the SRAM unit form two cross-coupled inverters. As shown, one inverter includes complementary transistors PT and NT connected in series, while the other inverter includes complementary transistor PC and NC connected in series. The output of one inverter drives the input of the other inverter, and vice versa. The two cross-coupled inverters form two complementary memory nodes QT and QC, one for storing a high (e.g., “1”) or low (e.g., “0”) data value and the other for storing a complementary low (e.g., “0”) or high (e.g., “1”) data value. Transistor PT functions as a load transistor for supplying a voltage (e.g., Vdd) for the high data value to the first memory node QT; transistor PC functions as a load transistor for supplying the voltage (e.g., Vdd) for the high data value to the second memory node QC; transistor NT functions as a drive transistor for supplying a voltage (e.g., a reference voltage Vss or ground) for the low data value to the first memory node QT; and transistor NC functions as a drive transistor for supplying the voltage (e.g., a reference voltage Vss or ground) for the low data value to the second memory node QC.

The SRAM unit 310 further includes access transistors 311 and 312. Access transistor 311 is coupled between the BLT line and the QT node, while access transistor 312 is coupled between the BLC line and the QC node, and both can be activated through the word line WL. The SRAM unit may include additional transistors to allow control of the SRAM unit via additional control signals if needed.

In certain embodiments, the voltages used to operate the NVSRAM cell 300 include Vdd, Vpp, Vbb, and Vrd. As examples, Vdd is about 0.8V (nominal CMOS voltage), Vpp is about 1.0V to 1.5V, Vbb is about −0.2V to −0.3V, and Vrd is about 0.2V to 0.4V.

Referring still to FIGS. 3A and 3B, the MRAM unit 320 includes a first MTJ circuit 320T coupled between the BLT line and the QC node, and a second MTJ circuit 320C coupled between the BLC line and the QT node. The first MTJ circuit 320T includes a first drive transistor 321 and a MTJ structure MTJ-T connected in series. The pin layer PL of the MTJ structure MTJ-T is coupled to the QC node either directly (FIG. 3A) or via the transistor 321 (FIG. 3B), while the free layer FL of MTJ-T is coupled to the BLT line via the transistor 321 (FIG. 3A) or directly (FIG. 3B). The second MTJ circuit 320C includes a transistor 322 and a MTJ structure MTJ-C connected in series. The pin layer PL of MTJ structure MTJ-C is coupled to the QT node either directly (FIG. 3A) or via the transistor 322 (FIG. 3B), and the free layer FL of MTJ-T is coupled to the BLC line via the transistor 322 (FIG. 3A) or directly (FIG. 3B).

Each of the first and second MTJ circuits can be programmed to switch between a low-resistance state (parallel or P-state) and a high-resistance state (anti-parallel or AP-state), as shown in FIGS. 3C and 3D. FIG. 3C shows an MTJ being programmed to switch to a parallel state (i.e., low resistance state, or logic “0” state) to store a “0” data value. To store a “0”, a current greater than a critical current is caused to flow through the MTJ circuit in the direction of arrow 331 (i.e., from the free layer FL of the MTJ to the pin layer PL of the MTJ). To obtain this current, a positive voltage (e.g., Vdd or Vpp) is applied to the corresponding bit line BL (BLT or BLC) while the corresponding Q node (QC or QT) is at a low voltage level (e.g., Vss), and a positive voltage Vpp is applied to the gate node of transistor MD via the word line MWL to turn on the transistor MD and connect the free layer FL of the MTJ to the corresponding bit line BL in the case of FIG. 3A (or to connect the pin layer of the MTJ to the corresponding Q node in the case of FIG. 3B).

FIG. 3D shows an MTJ being programmed to switch to an anti-parallel state (i.e., high resistance state, or logic “i” state) to store a “1” data value. To store a “1”, a current greater than a critical current is caused to flow through the MTJ circuit in the direction of arrow 332 (i.e., from the pin layer PL of the MTJ to the free layer FL of the MTJ). To obtain this current, the corresponding bit line BL (BLT or BLC) is grounded (or connected to Vss) while the corresponding Q node (QC or QT) is at a high voltage level (e.g., Vdd), and a positive voltage Vpp is applied to the gate node of transistor MD via the word line MWL to turn on the transistor MD and connect the free layer FL of the MTJ to the corresponding bit line BL in the case of FIG. 3A (or to connect the pin layer of the MTJ to the corresponding Q node in the case of FIG. 3B).

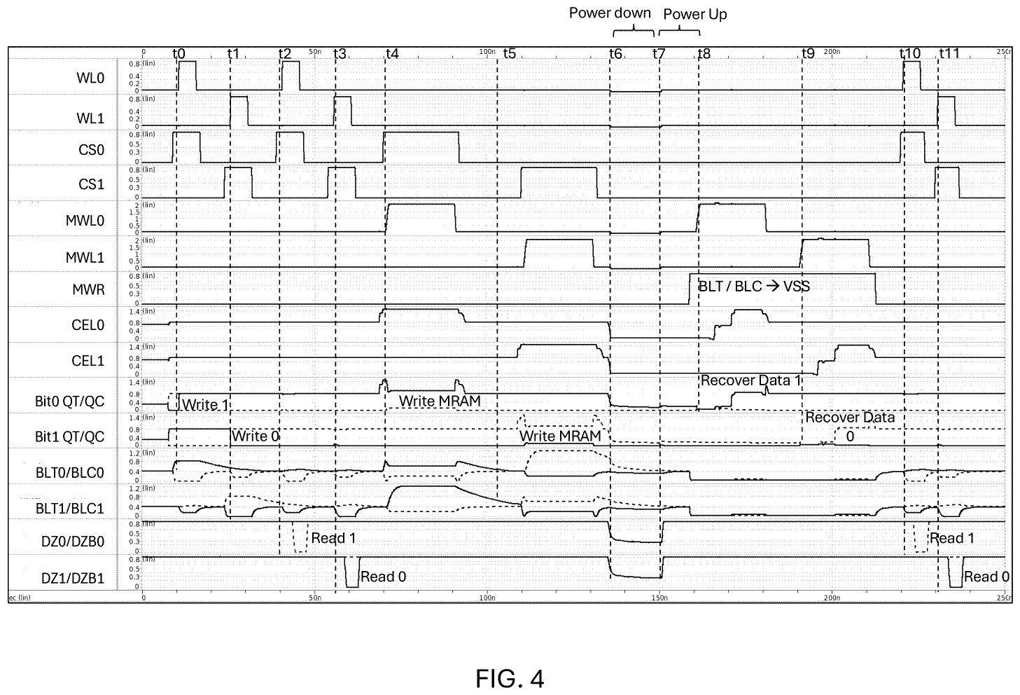

FIG. 4 includes simulated waveforms of various signals associated with a series of operations involving two NVSRAM cells, NVSRAM cell Bit0 (e.g., Bit 00) and NVSRAM cell Bit1 (e.g., Bit 11) in the NVSRAM array 101, according to certain embodiments. Each of the NVSRAM cell Bit0 and NVSRAM cell Bit1 can be configured as the NVSRAM cell 300 shown in FIG. 3A or 3B. NVSRAM cell Bit0 is coupled to the word lines WL0 and MW0, column select line CS0, VCEL line VCEL0, and bit line pair BLT0/BLC0. NVSRAM cell Bit1 is coupled to the word lines WL1 and MW1, column select lines CS1, VCEL line VCEL1, and bit line pair BLT1/BLC1.

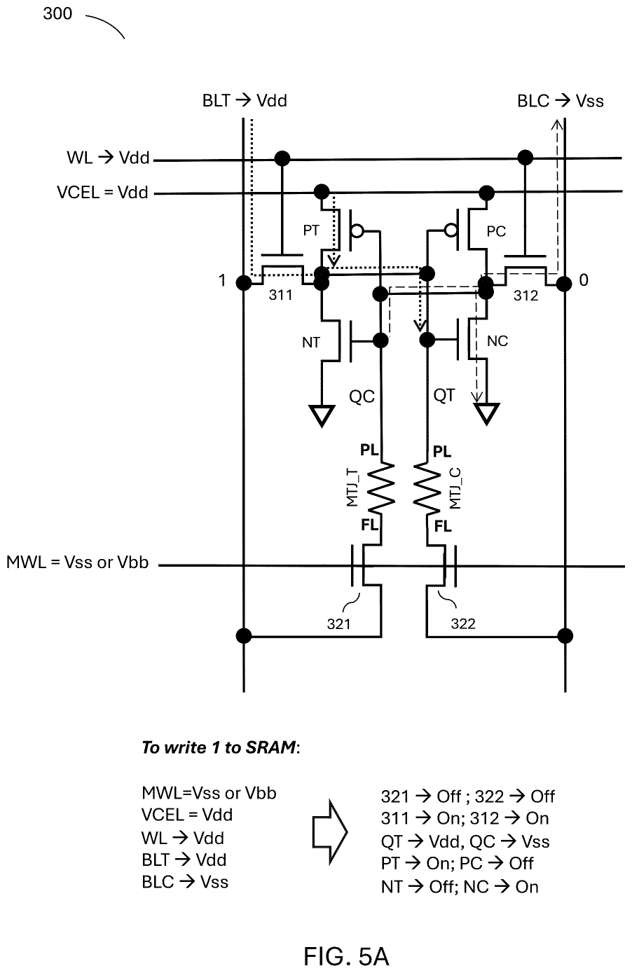

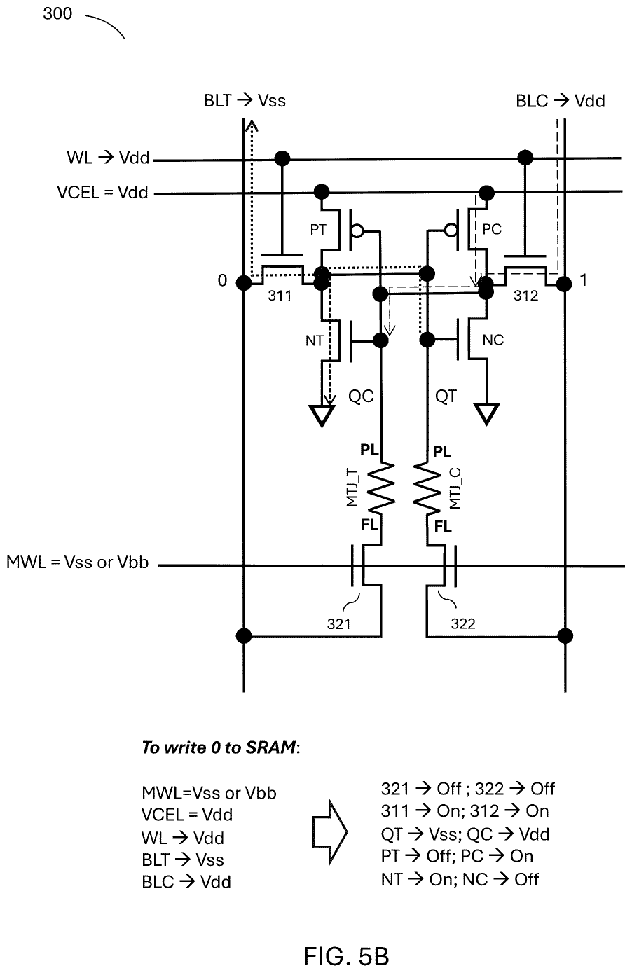

As shown in FIG. 4, at time to, an operation to write the data value of “1” into the SRAM unit of bit is started. For this operation, CS0 is elevated to Vdd, allowing the bit lines BLT0/BLC0 to be set to Vdd/Vss, respectively. At about the same time, the word line WL0 is set to Vdd. VCEL0 has been at Vdd and can remain there or be pumped higher. As shown in FIG. 5A, with the word line WL at Vdd, the access transistor 311 is turned on, which connects the QT node to the bit line BLT (at Vdd), which pulls the QT node up toward Vdd. With WL0 at Vdd, the access transistor 312 is also turned on and connects the QC node to the bit line BLC (at Vss), which pulls the QC node down toward Vss. The higher voltage at the QT node turns on the drive transistor NC, which connects the QC node to ground (or Vss). The higher voltage at the QT node also turns off the load transistor PC, which isolates the QC node from VCEL (at Vdd). On the other hand, the lower voltage at the QC node turns off the drive transistor NT, which isolates the QT node from ground (or Vss). The lower voltage at the QC node also turns on the load transistor PT, which connects the QT node at the VCEL line. Thus, at the end of the write cycle to write “1” to the NVSRAM cell, the QT node is held at Vdd via the load transistor PT while the QC node is held at Vss via the drive transistor NC, even after WL and BLT/BLC return to their respective default voltage levels. The dotted and dashed lines in FIG. 5A show direction of current flow during the write cycle.

Referring now to FIG. 4, at time t1, the data value of “0” is being written into the SRAM unit of bit1. or this operation, CS1 is elevated to Vdd, allowing the bit lines BLT1/BLC1 to be set to Vss/Vdd, respectively. At about the same time, the word line WL1 is set to Vdd. VCEL1 has been at Vdd and can remain there or be pumped higher. As shown in FIG. 5B, with the word line WL at Vdd, the access transistor 311 is turned on, which connects the QT node to the bit line BLT (at Vss), which pulls the QT node down toward Vss. Also, with WL0 at Vdd, the access transistor 312 is turned on and connects the QC node to the bit line BLC (at Vdd), which pulls the QC node up toward Vdd. The lower voltage at the QT node turns on the load transistor PC, which connects the QC node to VCEL (at Vdd). The lower voltage at the QT node also turns off the drive transistor NC, which isolates the QC node from ground (or Vss). On the other hand, the higher voltage at the QC node turns off the load transistor PT, which isolates the QT node from VCEL (at Vdd). The higher voltage at the QC node also turns on the drive transistor NT, which connects the QT node ground (or Vss). Thus, at the end of the write cycle to write “0” to the NVSRAM cell, the QT node is held at Vss or ground via the drive transistor NT while the QC node is held at Vdd via the load transistor PC, even after WL and BLT/BLC return to their respective default voltage levels. The dotted and dashed lines in FIG. 5B show direction of current flow during the write cycle.

Referring again to FIG. 4, from t2 to t4, Bit0 and subsequently Bit1 are read. As shown, reading from the NVSRAM cells can be done similarly as reading from standard SRAM units.

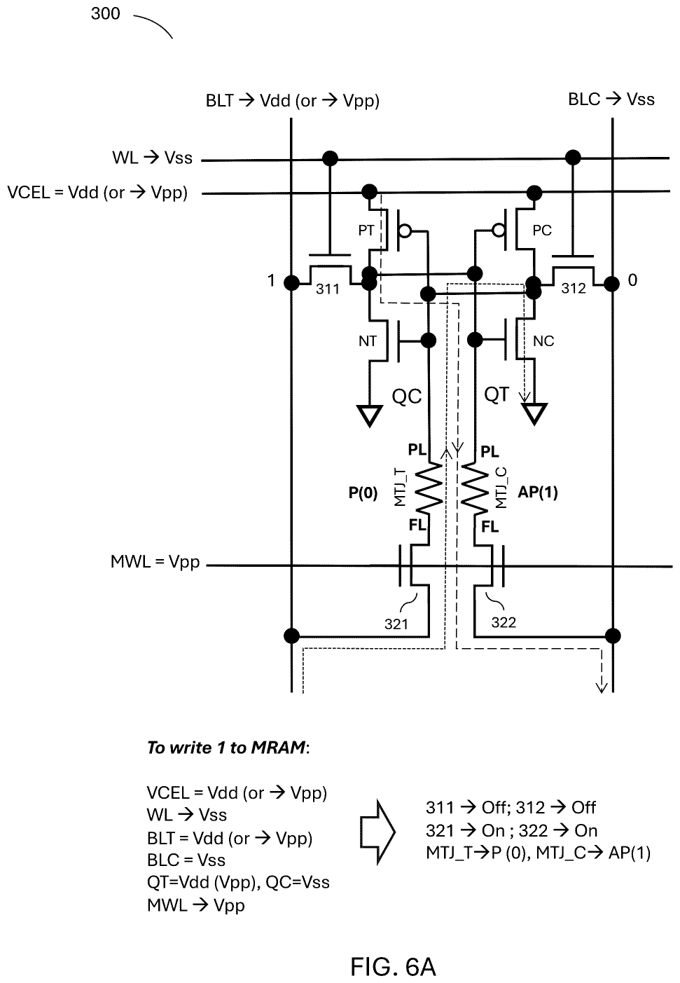

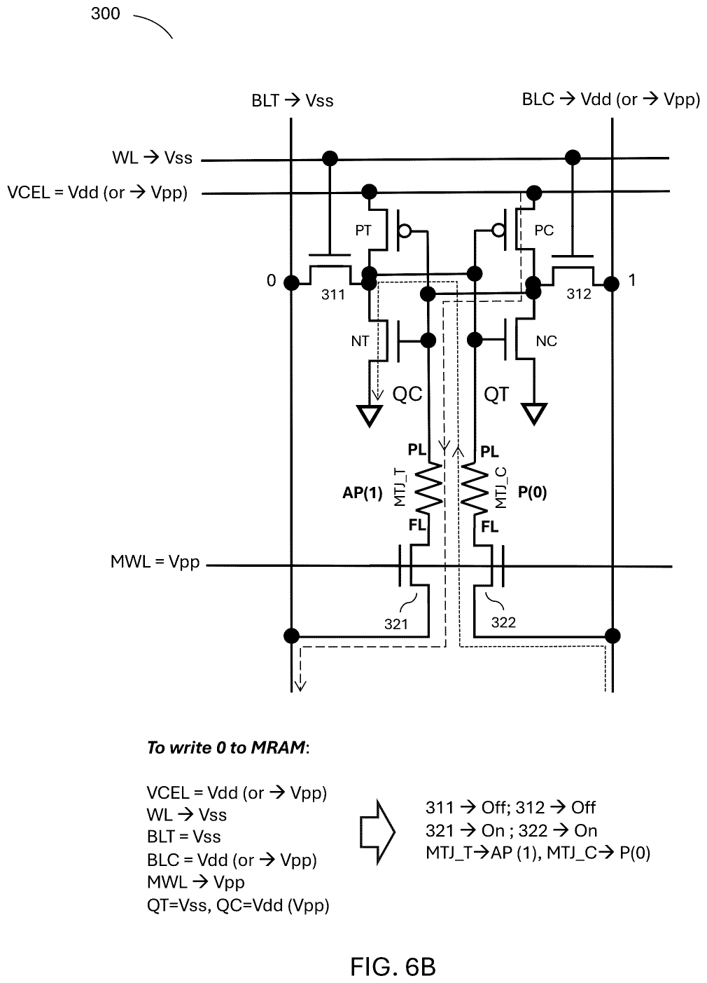

From t4 to t6, the NVSRAM device performs operations to back up the values stored in the SRAM units 310 of some or all of cells in an array 101 by writing them into the corresponding MRAM units 320. This can be done for the SRAM units of some or all of the cells in an array 101 when these NVSRAM cells 300 are standing by (i.e., not accessed by an external memory controller), under the control of the SRAM data recovery control device, or under the control of an external memory controller. As shown in FIG. 4, at t4, CS0 is raised to a high voltage value (e.g., Vdd) and kept there during the backup process, allowing BLT0 to be connected to Vdd and BLC1 be connected to ground (or Vss). At about the same time, VCEL0 is pumped up to Vpp, and MWL0 is raised to Vpp to activate transistors 321 and 322, causing current to flow through the MTJs between VCEL0 and the corresponding bit lines BLT0 and BLC0, as shown in FIG. 6A. The direction of the current flow through an MTJ depends on the voltage at the Q node the MTJ is coupled to. In the case that the SRAM unit is storing “1” (i.e., the QC node is at Vss and the QT node at Vdd), NT and PC are off, while NC and PT are on, causing current to flow from the pin layer PL of MTJ-C (which is coupled to the QT node that is now coupled to the VCEL line through transistor PT) to the free layer FL of the MTJ-C (which is now coupled to BLC via transistor 322 in the FIG. 3A implementation), setting or flipping MTJ-C to the AP state. This current thus charges up the BLC line, so it is pulled up from the ground (or Vss), as shown in FIG. 4. Meanwhile, another current flows from the free layer FL of MTJ-T (which is now coupled to BLT via transistor 321) to the pin layer PL of the MTJ-T (which is coupled to the QT node that is grounded via the transistor NT in the FIG. 3A implementation), setting or flipping MTJ-T to the P state. Thus, the value of “1” stored in the SRAM unit is written in the corresponding MRAM unit.

Note that this process can be carried out concurrently for all NVSRAM cells that are not being accessed by the memory controller (e.g., the process between t4 and t5 can be applied to an entire row or multiple rows of SRAM units). When multiple cells are involved, only the NVSRAM cells that store the value of “1” will be backed up between t4 and t5. For an NVSRAM cell where the corresponding SRAM unit is storing “0” (i.e., the QC node is at Vdd and the QT node at Vss), NC and PT are off, while NT and PC are on. As a result, the QC node is held at Vdd and the QT node held at Vss. No current flows through either MTJ-T or MTJ-C because the FL and PL of each MTJ is at the same voltage. Thus, the NVSRAM cells storing “0” are not affected by the write operation to back up the SRAM units storing “1.”

Referring again to FIG. 4, at t5, CS1 is raised to a high voltage value (e.g., Vdd), allowing BLC1 to be connected to Vdd and BLT1 to ground. At about the same time, VCEL is pumped to Vpp, and MWL is raised to Vpp to activate transistors 321 and 322, causing current to flow through the MTJs between the VCEL line and the corresponding bit lines BLT and BLC, as shown in FIG. 6B. The direction of the current flow through an MTJ depends on the voltage at the Q node the MTJ is coupled to. In the case that the SRAM unit is storing “0” (i.e., the QC node is at Vdd and the QT node at Vss), NC and PT are off, while NT and PC are on, causing current to flow from the pin layer PL of MTJ-T (which is coupled to the QC node that is now coupled to the VCEL line through transistor PC) to the free layer FL of the MTJ-T (which is now coupled to BLT via transistor 321 in the FIG. 3A implementation), setting or flipping MTJ-T to the AP state. Meanwhile, another current flows from the free layer FL of MTJ-C (which is now coupled to BLC via transistor 322 in the FIG. 3A implementation) to the pin layer PL of the MTJ-C, setting or flipping MTJ-C to the P state. Thus, the value of “0” stored in the SRAM unit is written in the corresponding MRAM unit.

Again, this process can be carried out concurrently for all NVSRAM cells that are not being accessed by the memory controller (e.g., the process between t5 and t6 can be applied to an entire row or multiple rows of SRAM units). When multiple cells are involved, only the NVSRAM cells that store the value of “0” will be backed up between t5 and t6. In the case that an NVSRAM cell's SRAM unit is storing “1” (i.e., the QC node is at Vss and the QT node at Vdd), NT and PC are off, while NC and PT are on. As a result, the QC node is held at Vss and the QT node held at Vdd. No current flows through either MTJ-T or MTJ-C because the FL and PL of each MTJ is at the same voltage. Thus, the NVSRAM cells storing “1” are not affected by the write operation to back up the SRAM units storing “0.”

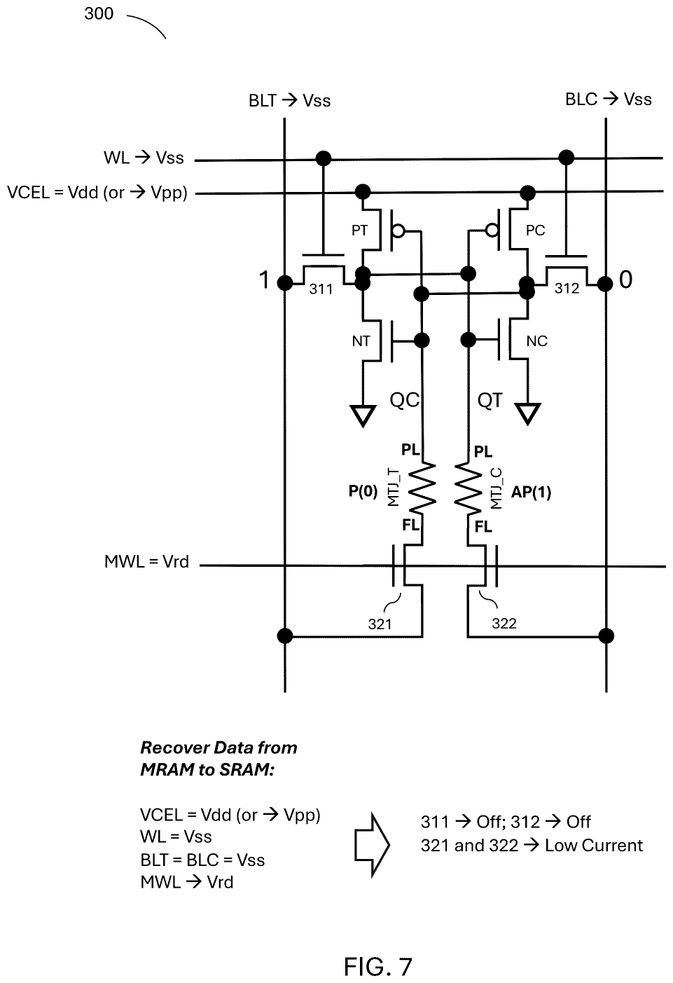

Referring again to FIG. 4, from t6 to t7, the NVSRAM device 100 experiences power failure. When power is restored between t7 and t8, the NVSRAM device 100 performs a set of operations to recover the lost data stored in the SRAM units before the power failure from their corresponding MRAM units under the control of the data recovery control device. As shown in FIGS. 4 and 7, to recover data “1” previously stored in the SRAM units coupled to a word line (e.g., WL0), the data recover control device is configured to raise the voltage of the corresponding MWL line to Vrd, or Vdd or Vpp, while keeping the bit lines BLT/BLC grounded (causing low current flowing through transistors 321 and 322). The VCEL line is raised to Vdd or pumped to Vpp, and the word line WL is grounded (turning off transistors 311 and 312). As a result, the Q node (QC or QT) will be set to Vdd or Vss depending on the state of the corresponding MTJ (MTJ-T or MTJ-C).

For example, when the MRAM unit is storing “1” (i.e., MTJ-T is at the P state and MTJ-C is at the AP state), QC is connected to BLT (at Vss), while QT is isolated from BLC (also at Vss). The grounding of QC turns on transistor PT and turns off transistor NT. Thus, QT is connected to VCEL via PT and isolated from ground by NT. With QT at Vdd (or higher), transistor PC is off and transistor NC is on. Thus, QC is isolated from VCEL by PC and held at ground by NC. Thus, the value of “1” is restored in the corresponding SRAM unit.

If the MRAM unit is storing “0” (i.e., MTJ-T is at the AP state and MTJ-C is at the P state), QT is connected to BLC (at Vss), while QC is isolated from BLT (also at Vss). The grounding of QT turns on transistor PC and turns off transistor NC. Thus, QC is connected to VCEL via PC and isolated from ground by NC. With QC at Vdd (or higher), transistor PT is off and transistor NT is on. Thus, QT is isolated from VCEL by PT and held at ground by NT. Thus, the value of “0” is restored in the corresponding SRAM unit.

After restoring the values held at the SRAM units before the power failure to the SRAM units in the row where Bit0 is located, the data recovery control device proceeds to restore the values held at the SRAM units in the row where Bit1 is located in the time period from t9 to t10, as shown in FIG. 4. In some embodiments, the data recovery control device is configured to restore the SRAM data values from row to row until most or all of the data values are recovered.

The terminology used in the description of the various described embodiments herein is for the purpose of describing particular embodiments only and is not intended to be limiting. As used in the description of the various described embodiments and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” is, optionally, construed to mean “when” or “upon” or “in response to determining” or “in response to detecting” or “in accordance with a determination that,” depending on the context.

The foregoing description, for purpose of explanation, has been described with reference to specific embodiments. However, the illustrative discussions above are not intended to be exhaustive or to limit the embodiments to the precise forms disclosed. Many modifications and variations are possible in view of the above teachings. The embodiments were chosen and described in order to best explain the principles and their practical applications, to thereby enable others skilled in the art to best utilize the embodiments and various embodiments with various modifications as are suited to the particular use contemplated.

What is claimed is:

1. A memory device, comprising:
memory cells arranged in n rows and m columns;
n variable supply voltage lines, each of the n variable supply voltage lines being coupled to memory cells in a respective row of the n rows;
n SRAM word lines, each of the n SRAM word lines being coupled to memory cells in a respective row of the n rows;
n MRAM word lines, each of the n MRAM word lines being coupled to memory cells in a respective row of the n rows; and
m bit line pairs, each bit line pair of the m bit line pairs being coupled to memory cells in a respective column of the m columns; wherein:
each memory cell includes an SRAM unit and a MRAM unit;
the SRAM unit includes first and second memory nodes programmable via the corresponding SRAM word line and the corresponding bit line pair to be at two complementary voltage levels, respectively;
the MRAM unit includes a first magnetic tunnel junction (MTJ) circuit, and a second MTJ circuit, the first MTJ circuit including a first transistor and a first MTJ structure, the first MTJ structure having a first pin layer and a first free layer on opposite sides of a first tunnel barrier layer, the second MTJ circuit including a second transistor and a second MTJ structure, the second MTJ structure having a second pin layer and a second free layer on opposite sides of a second tunnel barrier layer;
the first transistor has a first gate coupled to a corresponding MRAM word line and is configured to connect the first free layer to a first bit line of the corresponding bit line pair, or to connect the first pin layer to the first memory node, in response to a voltage on the corresponding MRAM word line exceeding a MTJ programming threshold; and
the second transistor has a second gate coupled to the corresponding MRAM word line and is configured to connect the second free layer to a second bit line of the corresponding bit line pair, or to connect the second pin layer to the second memory node, in response to the voltage on the corresponding MRAM word line exceeding the MTJ programming threshold.

2. The memory device of claim 1, wherein the first MTJ structure is configured to flip from an antiparallel (AP) state to a parallel (P) state in response to a first electric current from the first bit line to the first memory node exceeding a first threshold, and the second MTJ structure is configured to flip from an parallel (P) state to an antiparallel (AP) state in response to a second electric current from the second memory node to the second bit line exceeding a second threshold.

3. The memory device of claim 2, wherein the first MTJ structure is configured to flip from a parallel (P) state to an antiparallel (AP) state in response to a third electric current from the first memory node to the first bit line, the third electric current exceeding the second threshold, and the second MTJ structure is configured to flip from an antiparallel (AP) state to a parallel (P) state in response to a fourth electric current from the second bit line to the second memory node, the fourth electric current exceeding the first threshold.

4. The memory device of claim 2, wherein the first threshold is different from the second threshold.

5. The memory device of claim 2, further comprising a variable supply voltage control circuit configured to control the variable supply voltage lines, wherein:
the variable supply voltage control circuit is configured to output a first voltage to the corresponding variable supply voltage line when the first and second memory nodes are being programmed via the corresponding word line and the corresponding bit line pair to be at two complementary voltage levels, respectively; and
the variable supply voltage control circuit is configured to output a second voltage to the corresponding variable supply voltage line to enable the first electric current to exceed the first threshold and the second electric current to exceed the second threshold, the second voltage being higher than the first voltage.

6. The memory device of claim 1, wherein the first transistor has a first source terminal and a first drain terminal, one of the first source terminal and the first drain terminal is coupled to the first free layer and the other one of the first source terminal and the first drain terminal is coupled to the first bit line.

7. The memory device of claim 1, wherein the second transistor has a second source terminal and a second drain terminal, one of the second source terminal and the second drain terminal is coupled to the second free layer and the other one of the second source terminal and the second drain terminal is coupled to the second bit line.

8. The memory device of claim 1, wherein the first transistor has a first source terminal and a first drain terminal, one of the first source terminal and the first drain terminal is coupled to the first pin layer, and the other one of the first source terminal and the first drain terminal is coupled to the first memory node.

9. The memory device of claim 1, wherein the second transistor has a second source terminal and a second drain terminal, one of the second source terminal and the second drain terminal is coupled to the second pin layer, and the other one of the second source terminal and the second drain terminal is coupled to the second memory node.

10. The memory device of claim 1, further comprising a data recovery control logic configurable to, after the memory device experiencing power loss and in response to power to the memory device having been restored, cause the memory device to perform data recovery operations to recover data values stored in the memory cells immediately before the power loss, the data recovery operations including a first data recovery operation to recover data in an i^{th} row of the rows, and a second data recovery operation to recover data in an j^{th} row of the rows;
wherein the first data recover operation includes:
applying the second voltage to an i^{th} MRAM word line of the n MRAM word lines during an i^{th} data recovery period, the i^{th} MRAM word line corresponding to the i^{th} row; and
increasing a voltage on an i^{th} variable supply voltage line of the n variable supply voltage lines to the first voltage during the i^{th} data recovery period, the i^{th} variable supply voltage line corresponding to the i^{th} row;
wherein the first data recover operation includes:
applying the second voltage to an j^{th} MRAM word line of the n MRAM word lines during an j^{th} data recovery period subsequent to the i^{th} data recovery period, the j^{th} MRAM word line corresponding to the j^{th} row; and
increasing a voltage on an j^{th} variable supply voltage line of the n variable supply voltage lines to the first voltage during the j^{th} data recovery period, the j^{th} variable supply voltage line corresponding to the j^{th} row;
wherein the m bit line pairs are kept grounded during the data recovery operations.

11. A method of operating a memory device, the memory device including:
memory cells arranged in n rows and m columns;
n variable supply voltage lines, each of the n variable supply voltage lines being coupled to memory cells in a respective row of the n rows;
n SRAM word lines, each of the n SRAM word lines being coupled to memory cells in a respective row of the n rows;
n MRAM word lines, each of the n MRAM word lines being coupled to memory cells in a respective row of the n rows; and
m bit line pairs, each bit line pair of the m bit line pairs is coupled to memory cells in a respective column of the m columns;
the method comprising:
applying a first voltage to the corresponding variable supply voltage line during a first time period;
applying a second voltage to the corresponding MRAM word line during a second time period, the second time period overlapping with at least part of the first time period;
connecting a first bit line of the corresponding bit line pair to a third voltage during a third time period, the third time period overlapping at least partially with the first timer period;
connecting a second bit line of the corresponding bit line pair to a fourth voltage during a fourth timer period, the fourth time period overlapping at least partially with the third timer period, one of the third voltage and the fourth voltage is a supply voltage, and the other one of the third voltage and the fourth voltage is a reference voltage;
wherein:
each memory cell includes an SRAM unit and a MRAM unit;
the SRAM unit includes first and second memory nodes configurable to be at two complementary voltage levels, respectively;
the MRAM unit includes a first magnetic tunnel junction (MTJ) circuit, and a second MTJ circuit, the first MTJ circuit including a first transistor and a first MTJ structure, the first MTJ structure having a first pin layer and a first free layer on opposite sides of a first tunnel barrier layer, the second MTJ circuit including a second transistor and a second MTJ structure, the second MTJ structure having a second pin layer and a second free layer on opposite sides of a second tunnel barrier layer;
the first transistor has a first gate coupled to the corresponding MRAM word line and is configured to connect the first free layer to a first bit line of the corresponding bit line pair, or to connect the first pin layer to the first memory node, in response to the second voltage being applied to the corresponding MRAM word line during the second time period exceeding a MTJ programming threshold; and
the second transistor has a second gate coupled to the corresponding MRAM word line and is configured to connect the second free layer to a second bit line of the corresponding bit line pair, or to connect the second pin layer to the second memory node, in response to the second voltage being applied to the corresponding MRAM word line during the second time period.

12. The method of claim 11, wherein the first MTJ structure is configured to flip from an antiparallel (AP) state to a parallel (P) state in response to a first electric current from the first bit line to the first memory node, the first electric current exceeding a first threshold, and the second MTJ structure is configured to flip from an parallel (P) state to an antiparallel (AP) state in response to a second electric current from the second memory node to the second bit line, the second electric current exceeding a second threshold.

13. The method of claim 12, wherein the first MTJ structure is configured to flip from an parallel (P) state to an antiparallel (AP) state in response to a third electric current from the first memory node to the first bit line, the third electric current exceeding the second threshold, and the second MTJ structure is configured to flip from an antiparallel (AP) state to a parallel (P) state in response to a fourth electric current from the second bit line to the second memory node, the fourth electric current exceeding the first threshold.

14. The method of claim 12, wherein the first threshold is different from the second threshold.

15. The method of claim 12, further comprising applying a fifth voltage to the corresponding variable supply voltage line when the first and second memory nodes are being programmed via the corresponding word line and the corresponding bit line pair to be at two complementary voltage levels, respectively.
the variable supply voltage control circuit is configured to output a second voltage to the corresponding variable supply voltage line to enable the first electric current to exceed the first threshold and the second electric current to exceed the second threshold, the second voltage being higher than the first voltage.

16. The method of claim 11, further comprising, after the memory device experiencing power loss and in response to power to the memory device having been restored, performing data recovery operations to recover data values stored in the memory cells immediately before the power loss, the data recovery operations including a first data recovery operation to recover data in an i^{th} row of the rows, and a second data recovery operation to recover data in an j^{th} row of the rows;
wherein the first data recover operation includes:
applying the second voltage to an i^{th} MRAM word line of the n MRAM word lines during an i^{th} data recovery period, the i^{th} MRAM word line corresponding to the i^{th} row; and
increasing a voltage on an i^{th} variable supply voltage line of the n variable supply voltage lines to the first voltage during the i^{th} data recovery period, the i^{th} variable supply voltage line corresponding to the i^{th} row;
wherein the second data recover operation includes:
applying the second voltage to a j^{th} MRAM word line of the n MRAM word lines during a j^{th} data recovery period subsequent to the i^{th} data recovery period, the j^{th} MRAM word line corresponding to the j^{th} row; and
increasing a voltage on a j^{th} variable supply voltage line of the n variable supply voltage lines to the first voltage during the j^{th} data recovery period, the jthh variable supply voltage line corresponding to the j^{th} row;
wherein the m bit line pairs are kept grounded during the data recovery operations.

17. A method of operating a memory device, the memory device including:
memory cells arranged in n rows and m columns, each memory cell including an SRAM unit and a MRAM unit;
n variable supply voltage lines, each of the n variable supply voltage lines being coupled to memory cells in a respective row of the n rows;
n SRAM word lines, each of the n SRAM word lines being coupled to memory cells in a respective row of the n rows;
n MRAM word lines, each of the n MRAM word lines being coupled to memory cells in a respective row of the n rows; and
m bit line pairs, each bit line pair of the m bit line pairs is coupled to memory cells in a respective column of the m columns;
the method comprising:
writing into a plurality of memory cells during one or more write operations, the plurality of memory cells including first memory cells and second memory cells, wherein the one or more write operations cause the SRAM unit in each of the first memory cells to store a first data value and the SRAM unit in each of the second memory cells to store a second data value;
backing-up the first memory cells concurrently during a first time period, including, for each respective memory cell of the plurality of memory cells, applying a first voltage to a variable supply voltage line coupled to the each respective memory cell, applying a second voltage to a MRAM word line coupled to the each respective memory cell, connecting a first bit line of a bit line pair coupled to the each respective memory cell to a third voltage, and connecting a second bit line of the bit line pair coupled to the each respective memory cell to a fourth voltage;
backing-up the second memory cells concurrently during a second time period subsequent to the first time period, including, for each particular memory cell of the particular of memory cells, applying the first voltage to a variable supply voltage line coupled to the each particular memory cell, applying the second voltage to a MRAM word line coupled to the each particular memory cell, connecting a first bit line of a bit line pair coupled to the each particular memory cell to the fourth voltage, and connecting a second bit line of the bit line pair coupled to the each particular memory cell to the third voltage;
wherein backing up the first memory cells causes a first current to flow from the SRAM unit of each respective memory cell to flow through a first MTJ structure in the MRAM unit of the each respective memory cell to the first bit line and a second current to flow from the second bit line through a second MTJ structure in the MRAM unit of the each respective memory cell to the SRAM unit of the each respective memory cell, the first current setting the first MTJ structure to a high resistance (antiparallel or AP) state, the second current setting the second MTJ structure to a low resistance (parallel or P) state, resulting in the first data value stored in the SRAM unit in each respective first memory cell of the first memory cells to be written into the MRAM unit in the each respective first memory cell;
wherein backing up the second memory cells causes a third current to flow from the first bit line through a first MTJ structure in the MRAM unit of the each particular second memory cell to the SRAM unit of the each particular memory cell and a fourth current to flow from the SRAM unit of the each particular memory cell to flow through a second MTJ structure in the MRAM unit of the each particular memory cell to the second bit line, the third current setting the first MTJ structure to low resistance (parallel or P) state, the second current setting the second MTJ structure to a high resistance (antiparallel or AP) state, resulting in the second data value stored in the SRAM unit in each particular second memory cell of the second memory cells to be written into the MRAM unit in the each particular second memory cell.

18. The method of claim 17, further comprising, after the memory device experiencing power loss and in response to power to the memory device having been restored, performing data recovery operations to recover data values stored in the memory cells immediately before the power loss, the data recovery operations including a first data recovery operation to recover data in a first row and a second data recovery operation to recover data in a second row;
wherein the first data recover operation includes:
applying the second voltage to a first MRAM word line of the n MRAM word lines during a first data recovery period, the first MRAM word line corresponding to the first row; and
increasing a voltage on an first variable supply voltage line of the n variable supply voltage lines to the first voltage during the first data recovery period, the first variable supply voltage line corresponding to the first row;
wherein the second data recover operation includes:
applying the second voltage to a second MRAM word line of the n MRAM word lines during a second data recovery period subsequent to the first data recovery period, the second MRAM word line corresponding to the second row; and
increasing a voltage on a second variable supply voltage line of the n variable supply voltage lines to the first voltage during the second data recovery period, the second variable supply voltage line corresponding to the second row;
wherein the m bit line pairs are kept grounded during the data recovery operations.

19. The method of claim 17, wherein the plurality of memory cells are in the first row.

20. The method of claim 19, wherein one or more memory cells in the second row are accessed for read/write operation during the first time period and/or the second time period.
